(19) United States
(12) Patent Application Publication
(10) Pub. No.: US 2026/0026415 A1
(43) Pub. Date: Jan. 22, 2026

(54) CHIP PACKAGING STRUCTURE, ELECTRONIC DEVICE, AND PREPARATION METHOD

(71) Applicant: VIVO MOBILE COMMUNICATION CO., LTD., Guangdong (CN)

(72) Inventor: Guoyi ZHANG, Guangdong (CN)

(73) Assignee: VIVO MOBILE COMMUNICATION CO., LTD., Guangdong (CN)

(21) Appl. No.: 19/347,075

(22) Filed: Oct. 1, 2025

Related U.S. Application Data
(63) Continuation of application No. PCT/CN2024/086299, filed on Apr. 7, 2024.

(30) Foreign Application Priority Data
Apr. 14, 2023 (CN) 202310397337.X

(51) Int. Cl. H01L 23/498; H01L 21/48; H01L 23/00; H01L 23/538; H01L 25/065

(52) U.S. Cl. CPC H01L 23/49811; H01L 21/4853; H01L 23/5385; H01L 24/16; H01L 25/0657; H01L 2224/16145; H01L 2224/16227; H01L 2225/06513; H01L 2225/06517; H01L 2225/0652

(57) ABSTRACT

This application discloses a chip packaging structure, an electronic device, and a preparation method. The packaging structure includes: a first redistribution layer, chip wafers, a second redistribution layer, and a packaging layer. The first redistribution layer and the second redistribution layer are electrically connected to each other. The packaging layer is sandwiched between the first redistribution layer and the second redistribution layer. At least two stacked chip wafers are embedded in the packaging layer. Any two adjacent chip wafers are electrically connected to each other, and any of the chip wafers is electrically connected to at least one of the first redistribution layer and the second redistribution layer.

### CROSS-REFERENCE TO RELATED APPLICATIONS

This application is a Bypass continuation application of PCT International Application No. PCT/CN2024/086299 filed on Apr. 7, 2024, which claims the priority of Chinese Patent Application No. 202310397337.X filed in China on Apr. 14, 2023, which is incorporated herein by reference in its entirety.

### TECHNICAL FIELD

This application belongs to the field of electronic technologies, and specifically, to a chip packaging structure, an electronic device, and a preparation method.

### BACKGROUND

With the continuous development of electronic technologies, an electronic device has more implementable functions. As a result, the quantity and types of devices disposed on a chip packaging structure of the electronic device also increase, leading to a larger space occupied by the chip packaging structure and a larger volume of the chip packaging structure. A chip packaging structure in the related art is shown in FIG. 1A. To be specific, a current chip packaging structure includes a plurality of chip wafers stacked on a substrate, and the chip wafers are welded to the substrate by using solder balls. As can be seen, the current chip packaging structure has a relatively large volume.

### SUMMARY

This application aims to provide a chip packaging structure, an electronic device, and a preparation method.

According to a first aspect, an embodiment of this application provides a chip packaging structure, including: a first redistribution layer, chip wafers, a second redistribution layer, and a packaging layer. The first redistribution layer and the second redistribution layer are electrically connected to each other, and the packaging layer is sandwiched between the first redistribution layer and the second redistribution layer. At least two stacked chip wafers are embedded in the packaging layer. Any two adjacent chip wafers are electrically connected to each other, and any of the chip wafers is electrically connected to at least one of the first redistribution layer and the second redistribution layer.

According to a second aspect, an embodiment of this application provides an electronic device, including the foregoing chip packaging structure.

According to a third aspect, an embodiment of this application provides a preparation method for a chip packaging structure, including:
coating a first film layer on a carrier plate, and forming a first redistribution layer on the first film layer;
disposing at least two chip wafers sequentially stacked on a side of the first redistribution layer away from the carrier plate, where any two adjacent chip wafers are electrically connected to each other by using a first conductive connecting member;
filling a packaging layer on the at least two chip wafers, to package the at least two chip wafers; and
forming a second redistribution layer on a side of the packaging layer away from the first redistribution layer.

### BRIEF DESCRIPTION OF THE DRAWINGS

The foregoing and/or additional aspects and advantages of this application will become apparent and comprehensible in the description of the embodiments made with reference to the following accompanying drawings.

FIG. 1A is a schematic structural diagram of a chip packaging structure in the related art;

FIG. 1B is a schematic structural diagram of a chip packaging structure according to an embodiment of this application;

FIG. 2 is a schematic structural diagram of another chip packaging structure according to an embodiment of this application;

FIG. 3 is a schematic structural diagram of a supporting member in a chip packaging structure according to an embodiment of this application;

FIG. 4 is a first schematic structural diagram of a second redistribution layer in a chip packaging structure according to an embodiment of this application;

FIG. 5 is a second schematic structural diagram of a second redistribution layer in a chip packaging structure according to an embodiment of this application;

FIG. 6 is a flowchart of a preparation method for a chip packaging structure according to an embodiment of this application;

FIG. 7 is a first schematic structural diagram of a chip packaging structure in a preparation process according to an embodiment of this application;

FIG. 8 is a second schematic structural diagram of a chip packaging structure in a preparation process according to an embodiment of this application;

FIG. 9 is a third schematic structural diagram of a chip packaging structure in a preparation process according to an embodiment of this application; and

FIG. 10 is a fourth schematic structural diagram of a chip packaging structure in a preparation process according to an embodiment of this application.

### DETAILED DESCRIPTION

Embodiments of this application are described in detail below, and examples of the embodiments are shown in accompanying drawings, where the same or similar elements or the elements having same or similar functions are denoted by the same or similar reference numerals throughout the description. The embodiments described below with reference to the accompanying drawings are exemplary and used only for explaining this application, and should not be construed as a limitation on this application. All other embodiments obtained by a person of ordinary skill in the art based on the embodiments of this application without making creative efforts shall fall within the protection scope of this application.

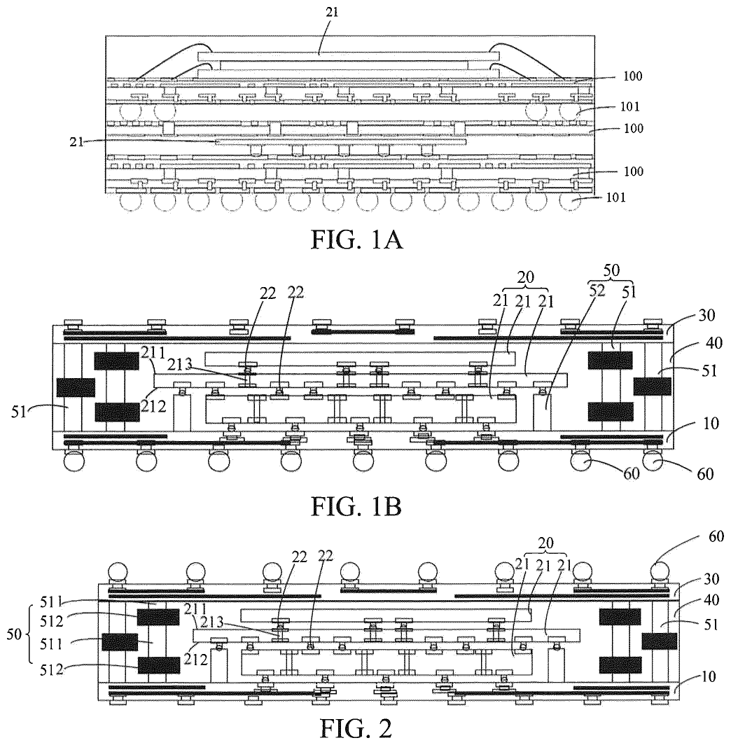

Refer to FIG. 1B and FIG. 2. FIG. 1B and FIG. 2 are schematic structural diagrams of a chip packaging structure according to an embodiment of this application. As shown in FIG. 1B and FIG. 2, the chip packaging structure includes: a first redistribution layer 10, chip wafers 21, a second redistribution layer 30, and a packaging layer 40. The packaging layer 40 is sandwiched between the first redistribution layer 10 and the second redistribution layer 30. At least two stacked chip wafers 21 are embedded in the packaging layer 40. Any two adjacent chip wafers 21 are electrically connected to each other, and any of the chip wafers 21 is electrically connected to at least one of the first redistribution layer 10 and the second redistribution layer 30.

The first redistribution layer 10, the packaging layer 40, and the second redistribution layer 30 may be understood as being stacked sequentially. That the packaging layer 40 is sandwiched between the first redistribution layer 10 and the second redistribution layer 30 may be understood as that two side surfaces of the packaging layer 40 facing away each other respectively abut against the first redistribution layer 10 and the second redistribution layer 30, or two side surfaces of the packaging layer 40 facing away each other respectively form gaps with the first redistribution layer 10 and the second redistribution layer 30, and the foregoing gaps may be filled with connecting members.

For a working principle of this embodiment of this application, refer to the following expressions.

The chip packaging structure includes the first redistribution layer 10 and the second redistribution layer 30. To be specific, the first redistribution layer 10 and the second redistribution layer 30 may be used for replacing a substrate. The first redistribution layer 10 and the second redistribution layer 30 are thinner than the substrate, thereby reducing an occupied space and further reducing a volume of the chip packaging structure. Additionally, the chip packaging structure includes at least two stacked chip wafers 21. In this way, as compared to the related art, a spacing between any two adjacent chip wafers 21 can be shortened, thereby further reducing the occupied space and further reducing the volume of the chip packaging structure. A chip packaging structure in the related art is shown in FIG. 1A. A plurality of chip wafers 21 are stacked on a substrate 100, and the chip wafers 21 are welded to the substrate 100 by using solder balls 101.

In addition, both the first redistribution layer 10 and the second redistribution layer 30 may be referred to as redistribution layers (RDL). An RDL packaging technology is a core technology in a wafer level packaging technology. The RDL may be used for electrical extension and interconnection on different planes in the chip packaging structure. Specifically, in the RDL, contact positions (I/O pad) of chip lines in an originally designed chip packaging structure are changed by wafer level metal distribution and bumping processes, so that the chip packaging structure is applicable to different package forms, and the RDL is thinner than the substrate in the related art.

The packaging layer 40 may be referred to as a molding compound (MC) layer.

The packaging layer 40 is located between the first redistribution layer 10 and the second redistribution layer 30, and the packaging layer 40 separately abuts against the first redistribution layer 10 and the second redistribution layer 30, to support the packaging layer 40, thereby reducing a warpage deformation quantity of the entire chip packaging structure. To be specific, the stiffness of the entire chip packaging structure is improved, and the service life is prolonged.

In addition, a module including at least two stacked chip wafers 21 may be referred to as a chip body 20. That the at least two stacked chip wafers 21 are embedded in the packaging layer 40 may be understood as that the chip body 20 is embedded in the packaging layer 40. To be specific, the packaging layer 40 may protect the chip body 20, thereby enhancing a waterproof and dirt-proof effect of the chip body 20. Additionally, the stiffness of the entire chip packaging structure can be further improved, thereby further prolonging the service life of the chip packaging structure.

A specific manner of electrical connection between any two adjacent chip wafers 21 is not limited herein. Optionally, any two adjacent chip wafers 21 may directly abut against each other, thereby implementing the electrical connection.

As another optional implementation, the chip wafer 21 includes a first surface and a second surface opposite to each other. A first conductive connecting member 22 is disposed on the first surface and/or the second surface. Any two adjacent chip wafers 21 are electrically connected to each other by using the first conductive connecting member 22.

In this implementation of this application, any two adjacent chip wafers 21 are electrically connected to each other by using the first conductive connecting member 22, so that the at least two chip wafers 21 may cooperate with each other, thereby improving the performance of the chip packaging structure, and also increasing the diversity of functions of the chip packaging structure.

It should be noted that a specific structure of the first conductive connecting member 22 is not limited herein. For example, the first conductive connecting member 22 may be a metal connecting member. In this way, a conduction effect between any two adjacent chip wafers 21 may be enhanced. Additionally, any two adjacent chip wafers 21 may be supported. To be specific, the strength of connection between any two adjacent chip wafers 21 is improved. Alternatively, the first conductive connecting member 22 may be a flexible connecting member. In this way, the diversity of the first conductive connecting member 22 is increased.

As an optional implementation, referring to FIG. 1B and FIG. 2, the chip wafer 21 is provided with a via communicating the first surface 211 with the second surface 212. The via is filled with a second conductive connecting member 213. The first surface 211 and the second surface 212 are electrically connected by using the second conductive connecting member 213.

A first surface 211 of a lower chip wafer 21 of any two adjacent chip wafers 21 is electrically connected to the first conductive connecting member 22, and a second surface 212 of an upper chip wafer 21 of any two adjacent chip wafers 21 is electrically connected to the first conductive connecting member 22. A second surface 212 of an upper chip wafer 21 of any two adjacent chip wafers 21 is electrically connected to a first surface 211 of a chip wafer 21 below the chip wafer 21 by using one first conductive connecting member 22, thereby implementing electrical connection between the upper chip wafer 21 of any two adjacent chip wafers 21 and the lower chip wafer 21.

In this implementation of this application, the via is filled with the second conductive connecting member 213, and the first surface 211 and the second surface 212 are electrically connected by using the second conductive connecting member 213. In this way, mutual electrical connection between the at least two chip wafers 21 in a stacking direction may be implemented. To be specific, vertical interconnection between the at least two chip wafers 21 may be implemented. Additionally, the at least two chip wafers 21 may implement signal transmission sequentially by using the first conductive connecting member 22 and the second conductive connecting member 213, to reduce a signal transmission delay and loss, improve a signal speed and bandwidth, and enhance a signal transmission effect.

As an optional implementation, the chip wafer 21 includes a silicon body layer. The via is provided in the silicon body layer.

The silicon body layer included in the chip wafer 21 is provided with a via communicating the first surface 211 with the second surface 212 of the chip wafer 21, and the via is filled with the second conductive connecting member 213, so that the first surface 211 and the second surface 212 are electrically connected by using the second conductive connecting member 213. The foregoing setting manner may be referred to as a through silicon via (TSV) technology.

In addition, the chip wafer 21 may include a silicon body layer, and may further include other functional layers. A quantity of the other functional layers is not limited herein. The other functional layers may be stacked sequentially. A positional relationship between the other functional layers and the silicon body layer is not limited herein. For example, the other functional layers may be disposed around the silicon body layer.

In this implementation of this application, the via is provided in the silicon body layer. In this way, the processing difficulty of providing the via can be reduced, and a phenomenon of damage to routing on the chip wafer 21 caused by drilling the via can also be reduced. To be specific, the impact of the via on routing on the chip wafer 21 is reduced.

As an optional implementation, referring to FIG. 1B, the chip packaging structure further includes a supporting member 50. The supporting member 50 is embedded in the packaging layer 40.

The supporting member 50 may be made of a conductive material. To be specific, the supporting member 50 may be a conductive member. For example, the supporting member 50 may be a copper column.

In this implementation of this application, the supporting member 50 is embedded in the packaging layer 40. In this way, the connection strength of the packaging layer 40 can be improved, thereby improving the strength of the chip packaging structure. Also, the supporting member 50 may further enhance a supporting function of the packaging layer 40 for the first redistribution layer 10 and the second redistribution layer 30, thereby further reducing the warpage deformation quantity of the entire chip packaging structure. To be specific, the stiffness of the entire chip packaging structure is further improved, and the service life of the chip packaging structure is further prolonged.

As an optional implementation, referring to FIG. 1B, the supporting member 50 includes a first supporting member 51. The first supporting member 51 separately abuts against the first redistribution layer 10 and the second redistribution layer 30, and the first redistribution layer 10 and the second redistribution layer 30 are electrically connected by using the first supporting member 51.

In this implementation of this application, the first supporting member 51 separately abuts against the first redistribution layer 10 and the second redistribution layer 30. To be specific, the first supporting member 51 may support the first redistribution layer 10 and the second redistribution layer 30. The first redistribution layer 10 and the second redistribution layer 30 are electrically connected by using the first supporting member 51. To be specific, the first supporting member 51 may have a conduction function. In this way, the first supporting member 51 integrates a supporting function and a conduction function, thereby reducing use of parts and lowering use costs.

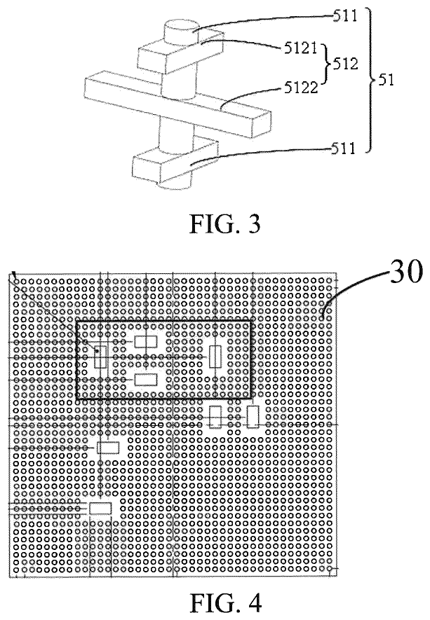

As an optional implementation, referring to FIG. 2 and FIG. 3, the first supporting member 51 includes a plurality of supporting columns 511 connected sequentially. A reinforced beam 512 is disposed at a connection point between adjacent supporting columns 511, and the reinforced beam 512 is disposed vertically to the supporting columns 511.

In this implementation of this application, the reinforced beam 512 is disposed at the connection point between the adjacent supporting column 511, to further improve connection strength between the adjacent supporting column 511, thereby further enhancing the supporting function of the packaging layer 40 for the first redistribution layer 10 and the second redistribution layer 30.

As an optional implementation, referring to FIG. 3, a plurality of reinforced beams 512 are provided, and the plurality of reinforced beams 512 include a first reinforced beam 5121 and a second reinforced beam 5122. A first vertical projection of the first reinforced beam 5121 on the first redistribution layer 10 and a second vertical projection of the second reinforced beam 5122 on the first redistribution layer 10 are staggered.

In this implementation of this application, that a first vertical projection of the first reinforced beam 5121 on the first redistribution layer 10 and a second vertical projection of the second reinforced beam 5122 on the first redistribution layer 10 are staggered may be understood as that the first reinforced beam 5121 and the second reinforced beam 5122 are disposed in different directions. In this way, different positions of the packaging layer 40 may be supported, and connection strength at different positions of the packaging layer 40 can be improved, thereby further reducing the warpage deformation quantity of the entire chip packaging structure. To be specific, the stiffness of the entire chip packaging structure is further improved, and the service life of the chip packaging structure is further prolonged.

For example, the first reinforced beam 5121 may be disposed along a northwest to southeast direction of a plane where the first redistribution layer 10 is located. The second reinforced beam 5122 may be disposed along a north-south direction of the plane where the first redistribution layer 10 is located. The plurality of reinforced beams 512 may further include a third reinforced beam, and the third reinforced beam may be disposed along an east-west direction of the plane where the first redistribution layer 10 is located.

In addition, the first supporting member 51 may be a frame structure. In this way, the first supporting member 51 may be used as a stress-bearing structure of the entire chip packaging structure, and may bear a stress load of the chip packaging structure, thereby reducing a warping deformation degree of the entire chip packaging structure under stress, so that the warping deformation degree is within a preset range, thereby improving the stability and security of the chip packaging structure.

It should be noted that a specific manner in which the first redistribution layer 10 and the second redistribution layer 30 are electrically connected by using the first supporting member 51 is not limited herein. As an optional implementation, the first redistribution layer 10 and the second redistribution layer 30 are directly electrically connected by using the first supporting member 51. To be specific, the first supporting member 51 may be used as a conduction member between the first redistribution layer 10 and the second redistribution layer 30.

As another optional implementation, a connecting line passes through the interior of the first supporting member 51. The first redistribution layer 10 and the second redistribution layer 30 are electrically connected by using the connecting line.

In this implementation of this application, the first redistribution layer 10 and the second redistribution layer 30 are electrically connected by using a connecting line passing through the interior of the first supporting member 51. In this way, the security performance of conduction can be improved. Additionally, the width of the connecting line is large as the first supporting member 51 is generally wide, so that the manner of transferring power by using the connecting line can reduce loss during power transfer.

It should be noted that the first redistribution layer 10 and the second redistribution layer 30 are electrically connected by using the connecting line in the first supporting member 51. In this way, the connecting line can improve the conductivity between the first redistribution layer 10 and the second redistribution layer 30, and the first supporting member 51 also has a supporting function. Thus, the quantity of parts can be reduced, and use costs can be lowered.

As another optional implementation, referring to FIG. 1B, the supporting member 50 includes a second supporting member 52. The second supporting member 52 is located between the first redistribution layer 10 and the second redistribution layer 30. A first end of the second supporting member 52 abuts against the first redistribution layer 10, and a second end of the second supporting member 52 abuts against one chip wafer 21 of the at least two chip wafers 21.

In this implementation of this application, the first end of the second supporting member 52 abuts against the first redistribution layer 10, and the second end of the second supporting member 52 abuts against one chip wafer 21 of the at least two chip wafers 21. In this way, a supporting function for the first redistribution layer 10 and the second redistribution layer 30 can be further enhanced. Additionally, the chip wafer 21 can also be supported.

In addition, the supporting member 50 includes the second supporting member 52. In this way, the supporting member 50 may include at least one of the first supporting member 51 and the second supporting member 52, and the first supporting member 51 and the second supporting member 52 are disposed at different positions, thereby increasing flexibility in position setting of the supporting member 50.

As an optional implementation, referring to FIG. 1B and FIG. 2, at least one of the first redistribution layer 10 and the second redistribution layer 30 is provided with a welding member 60.

The welding member 60 may include components such as a pad and a solder ball.

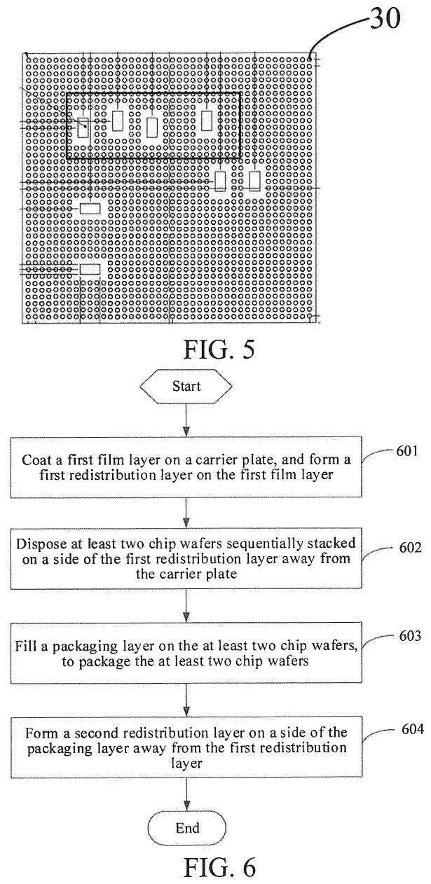

In addition, referring to FIG. 4 and FIG. 5, the first redistribution layer 10 may be provided with a plurality of pads, so that the pads may be provided with welding members 60, and may be electrically connected to another electronic device by using the welding members 60. A specific type of the another electronic device is not limited herein. For example, the another electronic device may be a main board of an electronic device.

In this implementation of this application, at least one of the first redistribution layer 10 and the second redistribution layer 30 is provided with the welding member 60, and may be electrically connected to another part (e.g., a main board) accordingly by using the welding member 60, thereby increasing the flexibility of an electrical connection position. Additionally, when the first redistribution layer 10 and the second redistribution layer 30 are both provided with a welding member 60, the chip packaging structure may include two active surfaces, thereby meeting layout design requirements of two different main boards, greatly reducing a development period of the chip packaging structure, and improving the effectiveness of collective reuse of raw materials of the chip packaging structure.

As an optional implementation, a plurality of first redistribution layers 10 are provided, and the plurality of first redistribution layers 10 are stacked sequentially. Additionally or alternatively, a plurality of second redistribution layers 30 are provided, and the plurality of second redistribution layers 30 are stacked sequentially.

In this implementation of this application, a plurality of first redistribution layers 10 are provided, and a plurality of second redistribution layer 30 are provided. In this way, the length and area of routing on the first redistribution layer 10 and the second redistribution layer 30 can be increased, thereby facilitating routing, and improving the use performance of the chip packaging structure.

An embodiment of this application further provides an electronic device, including the chip packaging structure in the foregoing embodiments. The electronic device provided in this embodiment of this application includes the chip packaging structure in the foregoing embodiments. Thus, the electronic device has the same beneficial technical effects as those in the foregoing embodiments. For a specific structure of the chip packaging structure, refer to related descriptions in the foregoing embodiments. Details are not described herein again.

An embodiment of this application provides a preparation method for a chip packaging structure. As shown in FIG. 6, the preparation method for a chip packaging structure includes the following steps:

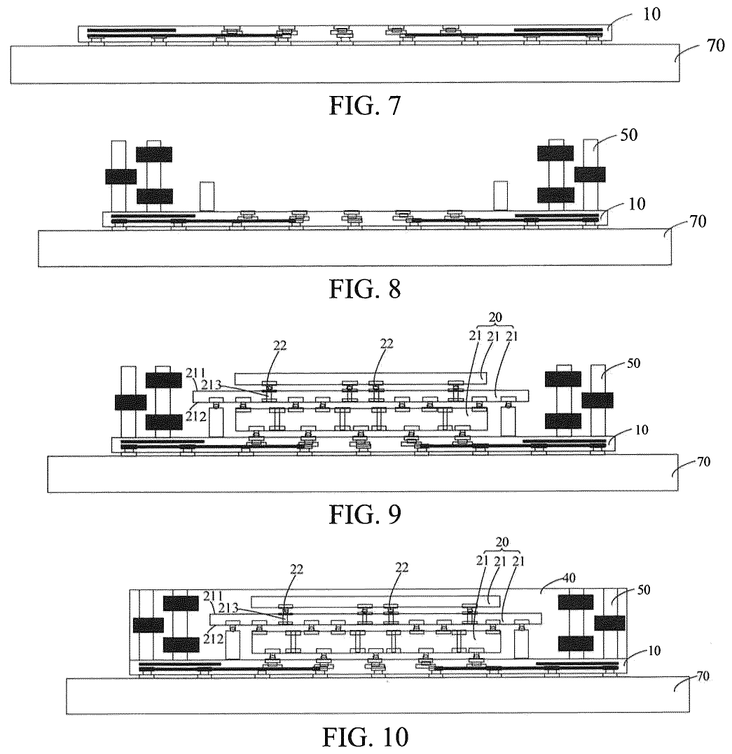

Step 601: Coat a first film layer on a carrier plate, and form a first redistribution layer on the first film layer. A module obtained in step 601 may be shown in FIG. 7. The module includes a carrier plate 70 and a first redistribution layer 10.

The carrier plate may be a prefabricated carrier plate. After a chip packaging structure is prepared, the carrier plate may be removed. To be specific, the carrier plate may be understood as a carrier that implements a supporting function in a package process of the chip packaging structure. The carrier plate does not belong to the chip packaging structure and is only used in the package process. The carrier plate may be a backboard made of glass, ceramics, metal, or another material that has a similar function and is compatible with a wafer level packaging process.

It should be noted that a structure obtained after the chip packaging structure is prepared and the carrier plate is removed may be shown in FIG. 1B and FIG. 2.

A specific type of the first film layer is not limited herein. For example, the first film layer may be at least one of the following film layers: an adhesion layer film layer, a sacrificed layer film layer, and a buffer layer film layer.

Step 602: Dispose at least two chip wafers sequentially stacked on a side of the first redistribution layer away from the carrier plate, where any two adjacent chip wafers are electrically connected to each other by using a first conductive connecting member.

For the chip wafers and the first conductive connecting members, refer to related descriptions in the foregoing embodiments. Details are not described herein again.

For processing steps between any two adjacent chip wafers, refer to the following expressions: A plurality of pads may be disposed on a first surface of one chip wafer of any two adjacent chip wafers, a plurality of pads may be disposed on a second surface of the other chip wafer of the any two adjacent chip wafers, and the first conductive connecting member is separately welded and fixed to the first surface and the second surface in a thermo compression bonding (TCB) welding manner.

Step 603: Fill a packaging layer on the at least two chip wafers, to package the at least two chip wafers.

For the packaging layer, refer to related descriptions in the foregoing embodiments. Details are not described herein again.

Step 604: Form a second redistribution layer on a side of the packaging layer away from the first redistribution layer.

In this embodiment of this application, through the foregoing steps, the prepared chip packaging structure may have a small volume and a small thickness. When the chip packaging structure is applied to an electronic device, the electronic device may have a small volume and a small thickness.

As an optional implementation, before the disposing at least two chip wafers sequentially stacked on a side of the first redistribution layer away from the carrier plate, the method further includes:
preparing a supporting member on the first redistribution layer.

The filling a packaging layer on the at least two chip wafers, to package the at least two chip wafers includes:
filling a packaging layer on the at least two chip wafers and the supporting member, to package the at least two chip wafers and the supporting member.

In this implementation, a structure obtained after the supporting member 50 is arranged on the first redistribution layer 10 may be shown in FIG. 8.

In addition, a structure obtained after filling the packaging layer 40 on the at least two chip wafers 21 and the supporting member 50, to package the at least two chip wafers 21 and the supporting member 50 may be shown in FIG. 10.

For the supporting member and the packaging layer, refer to related descriptions in the foregoing embodiments.

In this implementation of this application, by disposing the supporting member, a supporting effect can be achieved, thereby improving the connection strength of the entire chip packaging structure.

It should be noted that when the packaging layer is filled, the at least two chip wafers and the supporting member may be packaged in the packaging layer, so that the at least two chip wafers and the supporting member may be isolated from an external environment, thereby enhancing a protection effect on the at least two chip wafers and the supporting member.

Optionally, after the packaging layer is obtained, the packaging layer may further be ground, to reduce the thickness of the packaging layer, so that an end portion of the supporting member may be exposed from the packaging layer, to facilitate electrical connection to a second redistribution layer obtained in a subsequent step.

It should be noted that a type of the chip wafer is not limited herein. For example, the at least two chip wafers may include at least one of the following chip wafers: an application processor (AP) chip wafer and a dynamic random access memory (DRAM) chip wafer.

In addition, the first conductive connecting members for some chip wafers of the at least two chip wafers may further be welded and fixed to the supporting member, thereby enhancing a fixing and supporting effect on the chip wafers.

It should be noted that a disposition position of the supporting member is not limited herein.

As an optional implementation, the supporting member includes a first supporting member. The first supporting member separately abuts against the first redistribution layer and the second redistribution layer, and the first redistribution layer and the second redistribution layer are electrically connected by using the first supporting member.

The preparing a supporting member on the first redistribution layer includes:
preparing a supporting member on the first redistribution layer by using a first preset process,
where the first preset process includes at least one of the following: sputtering a seed layer, dry film lithography, developing, curing, electroplating, removing a photoresist, removing the seed layer, and plastic package.

In this implementation of this application, the supporting member is prepared on the first redistribution layer by using the first preset process, so that the preparation efficiency of the supporting member can be improved.

As an optional implementation, before the filling a packaging layer on the at least two chip wafers, to package the at least two chip wafers, the method further includes:
drilling a via in the chip wafer, and filling a second conductive connecting member in the via, where the chip wafer includes a first surface and a second surface opposite to each other, the via communicates the first surface with the second surface, and the first surface and the second surface are electrically connected to each other by using the second conductive connecting member.

A via is drilled in the chip wafer 21, and the second conductive connecting member 213 is filled in the via. A structure obtained thereafter is shown in FIG. 9.

In this implementation of this application, the via is drilled in the chip wafer, and the second conductive connecting member is filled in the via, to implement electrical connection between the first surface and the second surface of the chip wafer. In this way, an effect of the electrical connection between the first surface and the second surface of the chip wafer is relatively good. Additionally, as compared to a manner of separately disposing a connecting line on an outer surface of the chip wafer, an occupation volume of the chip wafer can be reduced, and the stability of electrical connection can be improved.

As an optional implementation, the drilling a via in the chip wafer includes:
drilling a via in the chip wafer by using a second preset process,
where the second preset process includes at least one of the following: photoresist marking, deep reactive ion etching, vapor deposition of a seed layer, copper electroplating filling, chemical mechanical polishing, or circuit layer fabrication.

The second preset process may be referred to as a TSV technology process.

In this implementation of this application, the via is drilled in the chip wafer by using the second preset process, so as to improve the efficiency of drilling the via and lower the costs of drilling the via.

As an optional implementation, the coating a first film layer on a carrier plate, and forming a first redistribution layer on the first film layer includes:
coating a first film layer on a carrier plate;
preparing a connecting layer on the first film layer; and
preparing the first redistribution layer on a first surface of the connecting layer, and preparing a bump metal layer on a second surface of the connecting layer, where the bump metal layer is used for preparing a welding member.

In this implementation of this application, the bump metal layer is prepared on the second surface of the connecting layer, and the bump metal layer is used for preparing the welding member. In this way, when the welding member is prepared, the preparation efficiency of the welding member can be improved, and the fixing effect of the welding member on the first redistribution layer can be enhanced.

As an optional implementation, the preparing the first redistribution layer on a first surface of the connecting layer includes:
preparing the first redistribution layer on a first surface of the connecting layer by using a third preset process,
where the third preset process includes at least one of the following: sputtering a seed layer, coating a dielectric layer, lithography, developing, curing at a temperature greater than a preset value, electroplating, and removing the seed layer.

The curing at a temperature greater than a preset value may be understood as high-temperature curing, and a specific magnitude of the preset value is not limited herein.

In this implementation of this application, the first redistribution layer is prepared on the first surface of the connecting layer by using the third preset process, thereby improving the preparation efficiency of the first redistribution layer and lowering the preparation costs of the first redistribution layer.

In the descriptions of this specification, descriptions using reference terms “an embodiment”, “some embodiments”, “an exemplary embodiment”, “an example”, “a specific example”, or “some examples” mean that specific characteristics, structures, materials, or features described with reference to the embodiment or example are included in at least one embodiment or example of this application. In this specification, exemplary descriptions of the foregoing terms do not necessarily refer to the same embodiment or example. In addition, the described specific features, structures, materials, or characteristics may be combined in a proper manner in any one or more of the embodiments or examples.

Although the embodiments of this application have been shown and described, a person of ordinary skill in the art should understand that various changes, modifications, replacements and variations may be made to the embodiments without departing from the principles and spirit of this application, and the scope of this application is as defined by the appended claims and their equivalents.

What is claimed is:

1. A chip packaging structure, comprising: a first redistribution layer, chip wafers, a second redistribution layer, and a packaging layer, wherein the first redistribution layer and the second redistribution layer are electrically connected to each other, and the packaging layer is sandwiched between the first redistribution layer and the second redistribution layer; at least two stacked chip wafers are embedded in the packaging layer; and any two adjacent chip wafers are electrically connected to each other, and any of the chip wafers is electrically connected to at least one of the first redistribution layer or the second redistribution layer.

2. The chip packaging structure according to claim 1, wherein the chip wafer comprises a first surface and a second surface opposite to each other, a first conductive connecting member is disposed on the first surface and/or the second surface, and any two adjacent chip wafers are electrically connected to each other by using the first conductive connecting member.

3. The chip packaging structure according to claim 2, wherein the chip wafer is provided with a via communicating the first surface with the second surface, the via is filled with a second conductive connecting member, and the first surface and the second surface are electrically connected by using the second conductive connecting member.

4. The chip packaging structure according to claim 1, further comprising a supporting member, wherein the supporting member is embedded in the packaging layer.

5. The chip packaging structure according to claim 4, wherein the supporting member comprises a first supporting member, the first supporting member separately abuts against the first redistribution layer and the second redistribution layer, and the first redistribution layer and the second redistribution layer are electrically connected by using the first supporting member.

6. The chip packaging structure according to claim 5, wherein the first supporting member comprises a plurality of supporting columns connected sequentially, a reinforced beam is disposed at a connection point between adjacent supporting columns, and the reinforced beam is disposed vertically to the supporting columns.

7. The chip packaging structure according to claim 6, wherein a plurality of reinforced beams is provided, the plurality of reinforced beams comprise a first reinforced beam and a second reinforced beam, and a first vertical projection of the first reinforced beam on the first redistribution layer and a second vertical projection of the second reinforced beam on the first redistribution layer are staggered.

8. The chip packaging structure according to claim 5, wherein a connecting line passes through the interior of the first supporting member, and the first redistribution layer and the second redistribution layer are electrically connected by using the connecting line.

9. The chip packaging structure according to claim 4, wherein the supporting member comprises a second supporting member, the second supporting member is located between the first redistribution layer and the second redistribution layer, a first end of the second supporting member abuts against the first redistribution layer, and a second end of the second supporting member abuts against one chip wafer of the at least two chip wafers.

10. The chip packaging structure according to claim 1, wherein a welding member is disposed on at least one of the first redistribution layer or the second redistribution layer.

11. The chip packaging structure according to claim 1, wherein a plurality of first redistribution layers is provided, and the plurality of first redistribution layers are stacked sequentially, and/or a plurality of second redistribution layers is provided, and the plurality of second redistribution layers are stacked sequentially.

12. An electronic device, comprising a chip packaging structure, wherein the chip packaging structure comprises: a first redistribution layer, chip wafers, a second redistribution layer, and a packaging layer, wherein the first redistribution layer and the second redistribution layer are electrically connected to each other, and the packaging layer is sandwiched between the first redistribution layer and the second redistribution layer; at least two stacked chip wafers are embedded in the packaging layer; and any two adjacent chip wafers are electrically connected to each other, and any of the chip wafers is electrically connected to at least one of the first redistribution layer or the second redistribution layer.

13. The electronic device according to claim 12, wherein the chip wafer comprises a first surface and a second surface opposite to each other, a first conductive connecting member is disposed on the first surface and/or the second surface, and any two adjacent chip wafers are electrically connected to each other by using the first conductive connecting member.

14. A preparation method for a chip packaging structure, comprising:
coating a first film layer on a carrier plate, and forming a first redistribution layer on the first film layer;
disposing at least two chip wafers sequentially stacked on a side of the first redistribution layer away from the carrier plate, wherein any two adjacent chip wafers are electrically connected to each other by using a first conductive connecting member;
filling a packaging layer on the at least two chip wafers, to package the at least two chip wafers; and
forming a second redistribution layer on a side of the packaging layer away from the first redistribution layer.

15. The method according to claim 14, wherein before the disposing at least two chip wafers sequentially stacked on a side of the first redistribution layer away from the carrier plate, the method further comprises:
preparing a supporting member on the first redistribution layer; and
the filling a packaging layer on the at least two chip wafers, to package the at least two chip wafers comprises:
filling a packaging layer on the at least two chip wafers and the supporting member, to package the at least two chip wafers and the supporting member.

16. The method according to claim 15, wherein the supporting member comprises a first supporting member, the first supporting member separately abuts against the first redistribution layer and the second redistribution layer, and the first redistribution layer and the second redistribution layer are electrically connected by using the first supporting member; and
the preparing a supporting member on the first redistribution layer comprises:
preparing a supporting member on the first redistribution layer by using a first preset process,
wherein the first preset process comprises at least one of the following: sputtering a seed layer, dry film lithography, developing, curing, electroplating, removing a photoresist, removing the seed layer, or plastic package.

17. The method according to claim 14, wherein before the filling a packaging layer on the at least two chip wafers, to package the at least two chip wafers, the method further comprises:
drilling a via in the chip wafer, and filling a second conductive connecting member in the via, wherein the chip wafer comprises a first surface and a second surface opposite to each other, the via communicates the first surface with the second surface, and the first surface and the second surface are electrically connected to each other by using the second conductive connecting member.

18. The method according to claim 17, wherein the drilling a via in the chip wafer comprises:
drilling a via in the chip wafer by using a second preset process,
wherein the second preset process comprises at least one of the following: photoresist marking, deep reactive ion etching, vapor deposition of a seed layer, copper electroplating filling, chemical mechanical polishing, or circuit layer fabrication.

19. The method according to claim 14, wherein the coating a first film layer on a carrier plate, and forming a first redistribution layer on the first film layer comprises:
coating a first film layer on a carrier plate;
preparing a connecting layer on the first film layer; and
preparing the first redistribution layer on a first surface of the connecting layer, and preparing a bump metal layer on a second surface of the connecting layer, wherein the bump metal layer is used for preparing a welding member.

20. The method according to claim 19, wherein the preparing the first redistribution layer on a first surface of the connecting layer comprises:
preparing the first redistribution layer on a first surface of the connecting layer by using a third preset process,
wherein the third preset process comprises at least one of the following: sputtering a seed layer, coating a dielectric layer, lithography, developing, curing at a temperature greater than a preset value, electroplating, or removing the seed layer.
